(19) United States
(12) Patent Application Publication
(10) Pub. No.: US 2026/0341640 A1
(43) Pub. Date: Oct. 29, 2026

(54) PULSED VOLTAGE WAVEFORM BIASING OF PLASMA

(71) Applicant: Applied Materials, Inc., Santa Clara, CA (US)

(72) Inventors: Shreeram Jyoti DASH, Newark, CA (US); Michael T. NICHOLS, Sunnyvale, CA (US)

(21) Appl. No.: 19/737,909

(22) Filed: Jul. 10, 2026

Related U.S. Application Data
(63) Continuation of application No. 18/535,724, filed on Dec. 11, 2023, now Pat. No. 12,683,123.

(51) Int. Cl. H01J 37/32

(52) U.S. Cl. CPC H01J 37/32174; H01J 37/32935; H01J 2237/3341

(57) ABSTRACT

Embodiments of the disclosure include apparatus (e.g., plasma processing systems) and methods for the plasma processing of a substrate in a processing chamber. Some embodiments are directed to a method for waveform generation, which generally includes delivering a radio frequency (RF) waveform at a frequency for a first period of time using a RF generator and then halting the delivery of the RF waveform for a second period of time, and delivering a pulsed voltage waveform at a first voltage for at least a portion of a third period of time using a pulser, wherein the delivery of the pulsed voltage waveform overlaps with the delivery of the RF waveform during a portion of the second period of time.

### CROSS-REFERENCE TO RELATED APPLICATIONS

This Application is a Continuation of Application 18/535,724 filed on Dec. 11, 2023, which is hereby incorporated by reference herein.

### BACKGROUND

### Field

Embodiments described herein generally relate to a system and methods used in semiconductor device fabrication. More specifically, embodiments of the present disclosure relate to a plasma processing system used to process a substrate.

### DESCRIPTION OF THE RELATED ART

Reliably producing high aspect ratio features is one of the key technology challenges for the next generation of semiconductor devices. One method of forming high aspect ratio features uses a plasma assisted etching process, such as a reactive ion etch (RIE) plasma process, to form high aspect ratio openings in a material layer, such as a dielectric layer, of a substrate. In a typical RIE plasma process, a plasma is formed in a processing chamber and ions from the plasma are accelerated towards a surface of a substrate to form openings in a material layer disposed beneath a mask layer formed on the surface of the substrate.

With technology nodes advancing towards 2 nanometers (nm), the fabrication of smaller features with larger aspect ratios requires atomic precision for plasma processing. For etching processes where the plasma ions play a major role, ion energy control is always challenging the development of reliable and repeatable device formation processes in the semiconductor equipment industry. In a typical plasma-assisted etching process, the substrate is positioned on a substrate support disposed in a processing chamber, a plasma is formed over the substrate by use of a radio frequency (RF) generator that is coupled to an electrode disposed on or within the plasma processing chamber, and ions are accelerated from the plasma towards the substrate across a plasma sheath. Additionally, RF substrate biasing methods, which require the use of a separate RF biasing source in addition to the RF generator that is used to initiate and maintain the plasma in the processing chamber, have been unable to desirably control the plasma sheath properties to achieve desirable plasma processing results that will allow the formation of these smaller device feature sizes. The traditional RF generator and RF biasing methods utilize sinusoidal RF waveforms to excite the plasma and form the plasma sheath often leads to undesirable and inconsistent process results due to sinusoidal shape of the RF waveform and the inability of the RF biasing methods to adjust the ion energy during processing due to limitations in the provided sinusoidal waveform characteristics.

Accordingly, there is a need in the art for a desirable plasma-assisted process that solves the problems described above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments of the present disclosure provide a method for waveform generation. The method generally includes delivering a radio frequency (RF) waveform at a frequency for a first period of time using a RF generator and then halting the delivery of the RF waveform for a second period of time, and delivering a pulsed voltage waveform at a first voltage for at least a portion of a third period of time using a pulser, wherein the delivery of the pulsed voltage waveform overlaps with the delivery of the RF waveform during a portion of the second period of time.

Embodiments of the present disclosure provide a waveform generator. The waveform generator generally includes a system controller coupled to the waveform generator. The system controller generally includes memory that includes computer- executable instructions and one or more processors configured to execute the computer-executable instructions and cause the waveform generator to deliver a radio frequency (RF) waveform at a frequency for a first period of time using a RF generator and then halting the delivery of the RF waveform for a second period of time, and deliver a pulsed voltage waveform at a first voltage for at least a portion of a third period of time using a pulser, wherein the delivery of the pulsed voltage waveform overlaps with the delivery of the RF waveform during a portion of the second period of time.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic representation of an example processing system, in which embodiments of the present disclosure may be implemented.

FIG. 2 illustrates a graph of two separate voltage waveforms that are established on a substrate due to a voltage waveform applied to an electrode of a processing chamber, in accordance with certain embodiments of the present disclosure.

FIG. 3 is a flow diagram illustrating a method of waveform generation, according to one or more of the embodiments described herein.

FIG. 4 illustrates a graph of example radio frequency (RF) generator power used to generate an RF waveform and example pulser voltage used to generate a pulsed voltage waveform during the method of waveform generation, according to one or more of the embodiments described herein.

FIG. 5 illustrates another graph of example radio frequency (RF) generator power used to generate an RF waveform and example pulser voltage used to generate a pulsed voltage waveform, according to one or more of the embodiments described herein.

FIG. 6 illustrates another graph of example radio frequency (RF) generator power used to generate an RF waveform and example pulser voltage used to generate a pulsed voltage waveform, according to one or more of the embodiments described herein.

FIG. 7 illustrates another graph of example radio frequency (RF) generator power used to generate an RF waveform and example pulser voltage used to generate a pulsed voltage waveform, according to one or more of the embodiments described herein.

FIG. 8 illustrates another graph of example radio frequency (RF) generator power used to generate an RF waveform and example pulser voltage used to generate a pulsed voltage waveform, according to one or more of the embodiments described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure generally relate to apparatus and methods for performing plasma-assisted processes. More specifically, embodiments provided herein provide for controlling a plasma during processing by controlling the delivery of a pulsed radio frequency (RF) waveform and a pulsed voltage (PV) waveform. In some embodiments, the process of controlling the plasma includes controlling an overlap in time between a pulse of the pulsed RF waveform and a series of pulses included within the PV waveform. It has been found that by controlling the delivery and overlap in time of pulses of a pulsed RF waveform and a series of bursts of voltage pulses within a PV waveform can be used to improve the plasma processing results on a substrate during plasma processing. In one example, it has been found that by controlling the process parameters of the PV waveform during one or more bursts of voltage pulses, the plasma properties can be controlled to achieve improved processing results, such as improved narrow aspect-ratio etch results and better profile control on a substrate during plasma processing. In general, a burst of voltage pulses within a PV waveform will include a series of voltage pulse that can be provided to an electrode within a plasma processing chamber. An example of the process parameters of the PV waveform can include the PV on-time, the PV pulse duty cycle, the pulsing frequency, PV pulse burst length, and the voltage set- point of the PV waveform. These process parameters may be manipulated as desired to provide enhanced control of the plasma-assisted processes when compared to conventional plasma-assisted processes that only utilize the delivery of an RF waveform or a pulsed RF waveform to control the plasma during processing.

### Processing System Examples

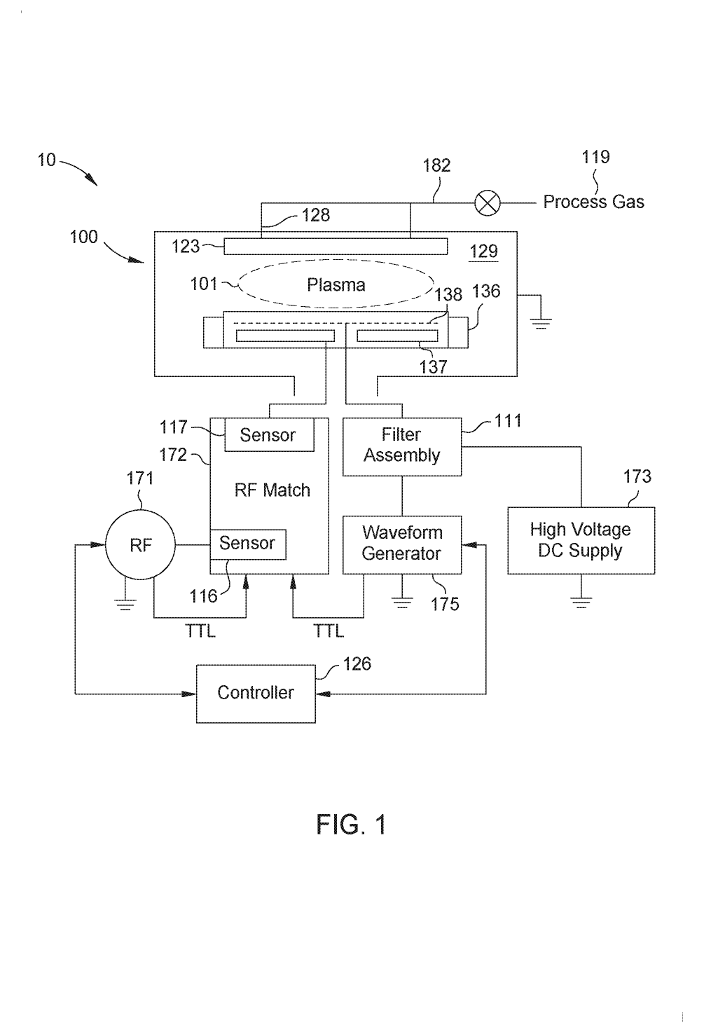

FIG. 1 is a schematic representation of an example processing system 10. The plasma processing system 10 is configured for plasma-assisted etching processes, such as a reactive ion etch (RIE) plasma processing. The plasma processing system 10 can also be used in other plasma-assisted processes, such as plasma-enhanced deposition processes (for example, plasma-enhanced chemical vapor deposition (PECVD) processes, plasma-enhanced physical vapor deposition (PEPVD) processes, plasma-enhanced atomic layer deposition (PEALD) processes, plasma treatment processing, plasma-based ion implant processing, or plasma doping (PLAD) processing. In some embodiments, as shown in FIG. 1, the plasma processing system 10 is configured to form a capacitively-coupled-plasma (CCP). In other embodiments, a plasma may alternately be generated by an inductively coupled plasma (ICP) source disposed over a processing region of the plasma processing system 10.

The plasma processing system 10 includes a processing chamber 100, a substrate support assembly 136, a gas delivery system 182, a high voltage direct current (DC) supply 173, a RF generator 171, and an RF match 172 (e.g., RF impedance matching network). A chamber lid 123 includes one or more sidewalls and a chamber base that are configured to withstand the pressures and energy applied to them while a plasma 101 is generated within a vacuum environment maintained in a processing volume 129 of the processing chamber 100 during processing.

The gas delivery system 182, which is coupled to the processing volume 129 of the processing chamber 100 is configured to deliver at least one processing gas from at least one gas processing source 119 to the processing volume 129 of the processing chamber 100. The gas delivery system 182 includes the processing gas source 119 and one or more gas inlets 128 positioned through the chamber lid 123. The gas inlets 128 are configured to deliver one or more processing gasses to the processing volume 129 of the processing chamber 100.

The processing chamber 100 includes a chamber lid 123 and a substrate support assembly 136 positioned in the processing volume 129 of the processing chamber 100. In some embodiments, the chamber lid 123 is grounded and thus acts as an upper electrode during plasma processing. In some embodiments, the RF generator 171 is electrically coupled to a first lower electrode, such as the RF baseplate 137. The RF generator 171 is configured to deliver an RF signal to ignite and maintain the plasma 101 between the upper and lower electrodes. In one example, the RF generator 171 may deliver an RF source power to the RF baseplate 137 within the substrate support assembly 136 (e.g., a cathode assembly) for plasma production. However, in some alternative configurations, the RF generator 171 can be electrically coupled to the upper electrode. A center frequency of the RF source power can be from 13.56 MHz to very high frequency band such as 40 MHz, 60 MHz, 120 MHz or 162 MHz. The RF source power can be operated in a continuous mode or a pulsed mode. A pulsing frequency of the RF power can be from 100 to 10 kHz, and duty cycles are ranging from 5% to 95%. The RF generator 171 has a frequency tuning capability and can adjust its RF power frequency within e.g., ±5% or ±10%. In some embodiments, the RF generator 171 switches the RF power frequency at a predefined speed (e.g., two nanoseconds, fifty nanoseconds, etc.).

The substrate support assembly 136 is coupled to the RF generator 171 configured to deliver an RF signal to the processing volume 129 of the processing chamber 100. The RF generator 171 is electronically coupled to the RF match 172 disposed between the RF generator 171 and the processing volume 129 of the processing chamber 100. For example, the RF match 172 is an electrical circuit used between the RF generator 171 and a plasma reactor (e.g., the processing volume 129 of the processing chamber 100) to optimize power delivery efficiency. One or more RF filters (e.g., within the RF match 172) are designed to only allow powers in a selected frequency range, and to isolate RF power supplies from each other. In some cases, a bandwidth of an RF filter has to be larger than a frequency tuning range of the RF generator 171.

During the plasma processing, the RF generator 171 delivers an RF signal to the RF baseplate 137 of the substrate support assembly 136 via the RF match 172. For example, the RF signal is applied to a load (e.g., gas) in the processing volume 129 of the processing chamber 100. If an impedance of the load is not properly matched to an impedance of a source (e.g., the RF generator 171), a portion of a waveform can reflect back in an opposite direction. Accordingly, to prevent a substantial portion of the waveform from reflecting back, it is necessary to find a match impedance (e.g., a matching point) by adjusting one or more components of the RF match 172 as the source and load impedances change.

The RF match 172 is electrically coupled to the RF generator 171, the substrate support assembly 136, and the PV waveform generator 175. The RF match 172 is configured to receive a synchronization signal from either or both of the RF generator 171 and the PV waveform generator 175.

The substrate support assembly 136 may be coupled to a high voltage DC supply 173 that supplies a chucking voltage thereto. The high voltage DC supply 173 may be coupled to a filter assembly 178 that is disposed between the high voltage DC voltage supply 173 and the substrate support assembly 136. The filter assembly 178 is configured to electronically isolate the high voltage DC supply 173 during plasma processing. In one configuration, a static DC voltage is between about -5000V and about 5000V and is delivered using an electrical conductor (such as a coaxial power delivery line). The filter assembly 178 may include multiple filtering components or a single common filter.

The substrate support assembly 136 is also coupled to a PV waveform generator 175 configured to supply a PV to an electrode within the substrate support assembly 136 to bias a substrate disposed on the substrate support. The PV waveform generator 175 may be coupled to the RF baseplate 137 or a second electrode disposed within the substrate support assembly 136, such as the chucking electrode 138. The PV waveform generator 175 is coupled to the filter assembly 178, which is coupled to the electrode disposed within the substrate support assembly 136. The filter assembly 178 is disposed between the PV waveform generator 175 and the substrate support assembly 136. The filter assembly 178 is configured to electronically isolate the PV waveform generator 175 from at least the RF signal provided by the RF generator 171 during plasma processing.

The RF generator 171 and the PV waveform generator 175 are each directly coupled to a system controller 126. The system controller 126 synchronizes the respective generated RF signal and PV waveform.

Voltage and current sensors can be placed at an input and/or output of the RF match 172 to measure impedance and other parameters. These sensors can be synchronized using an external transistor-transistor logic (TTL) synchronization signal from an advanced waveform generator and/or RF generators or using measured voltage and current data to determine timing internally. For example, an output sensor 117 is configured to measure the impedance of the plasma processing chamber 100, and other characteristics such as the voltage, current, harmonics, phase, and/or the like. An input sensor 116 is configured to measure the impedance of the RF generator 171 and other characteristics such as the voltage, current, harmonics, phase, and/or the like. Based on either of the synchronization signals or the characteristics of the plasma processing chamber 100, the RF match 172 is able to capture fast impedance changes and optimize impedance matching.

The PV waveform generator 175 is used to supply a PV waveform and/or a tailored voltage waveform, which is a sum of harmonic frequencies associated with the waveform. The PV waveform generator 175 may output a synchronization TTL signal to the RF match 172. The voltage waveform is coupled to a bias electrode (e.g., a bias electrode 104 shown in FIG. 1B) through the filter assembly 178. The high voltage DC supply 173 is applied to chuck a wafer during a process for a thermal control. In some cases, there can be a third electrode at an edge of the cathode assembly for edge uniformity control.

### Voltage Waveform Examples

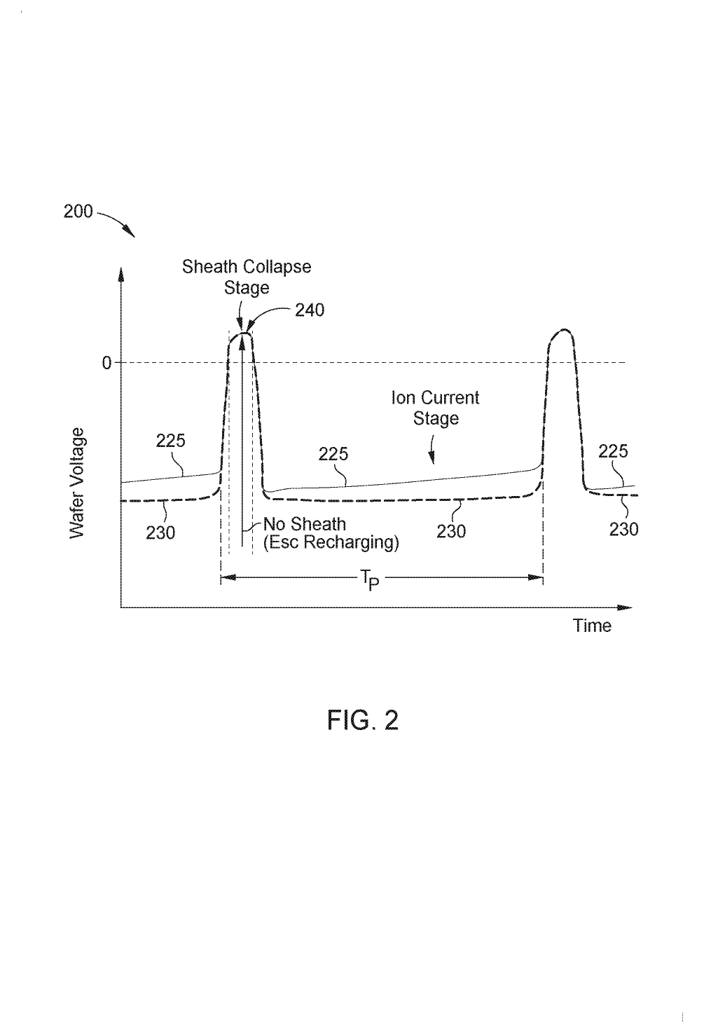

FIG. 2 illustrates a graph 200 of two separate voltage waveforms established at the substrate 103 disposed on the substrate receiving surface 105A of the substrate support assembly 136 of the processing chamber 100 due to the delivery of PV waveforms to the bias electrode 104 of the processing chamber 100. A first waveform (e.g., a waveform 225) is an example of a non-compensated PV waveform established at the substrate 103 during the plasma processing. A second waveform (e.g., a waveform 230) is an example of a compensated PV waveform established at the substrate 103 by applying a negative slope waveform to the bias electrode 104 of the processing chamber 100 during an “ion current stage” portion of the PV waveform cycle by use of the current source 177. The compensated PV waveform can alternatively be established by applying a negative voltage ramp during the ion current stage of the PV waveform generated by the PV waveform generator 175. The PV waveform cycle of the waveforms 225, 230 each have a period Tₚ, which is, for example, typically between 2 microsecond (µs) and 10 µs, such as 2.5 µs. The ion current stage of the PV waveform cycle will typically take up between about 50% and about 95% of the period Tₚ, such as from about 80% to about 90% of the period Tₚ.

The waveforms 225 and 230 include two main stages: an ion current stage and a sheath collapse stage. Both portions (e.g., the ion current stage and the sheath collapse stage) of the waveforms 225 and 230, can be alternately and/or separately established at the substrate 103 during the plasma processing. At a beginning of the ion current stage, a drop in the voltage at the substrate 103 is created, due to the delivery of a negative portion of the PV waveform (e.g., the ion current portion) provided to the bias electrode 104 by the PV waveform generator 175, which creates a high voltage sheath above the substrate 103. The high voltage sheath allows the plasma generated positive ions to be accelerated towards the biased substrate 103 during the ion current stage, and thus, for RIE processes, controls the amount and characteristics of the etching process that occurs on the surface of the substrate 103 during the plasma processing. The sheath collapse stage includes a positive voltage swing 240 (e.g., as a result of the positive wafer voltage), and the ion current stage includes a negative voltages swing (e.g., as a result of the positive wafer voltage), as illustrated in FIG. 2. In some embodiments, it is desirable for the ion current stage to include a region of the PV waveform that achieves the voltage at the substrate 103 that is stable or minimally varying throughout the stage, as illustrated in FIG. 2 by the waveform 230. One will note that significant variations in the voltage established at the substrate 103 during the ion current stage, such as shown by the positive slope in the waveform 225, will undesirably cause a variation in the ion energy distribution (IED) and thus cause undesirable characteristics of the etched features to be formed in the substrate 103 during the RIE process. Plasma sheath impedance varies with supplied PV waveform voltages. The RF match 172 can use either or both of the synchronization signals and/or use its internal sensors to sample impedances in different processing phases. In one example, a synchronization signal or characteristics determined by the input sensor 116 or the output sensor 117 are used to trigger the RF match 172 to determine at least two different impendences at different processing stages. Then, the RF match 172 updates its matching point based on the at least two different impedances.

### Process Monitoring and Control Examples

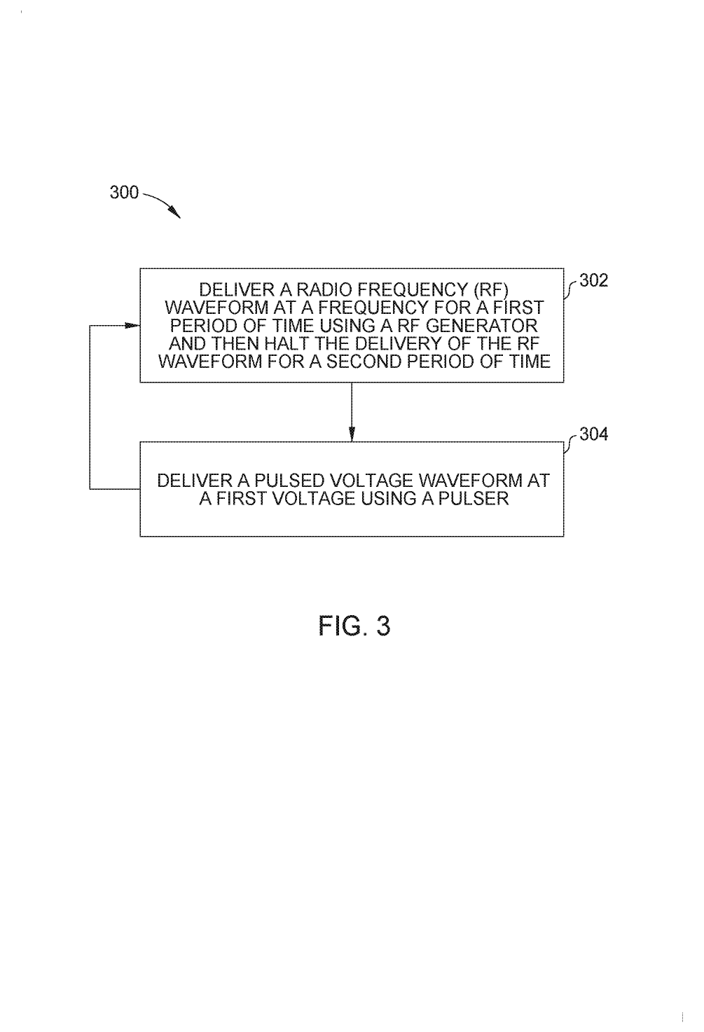

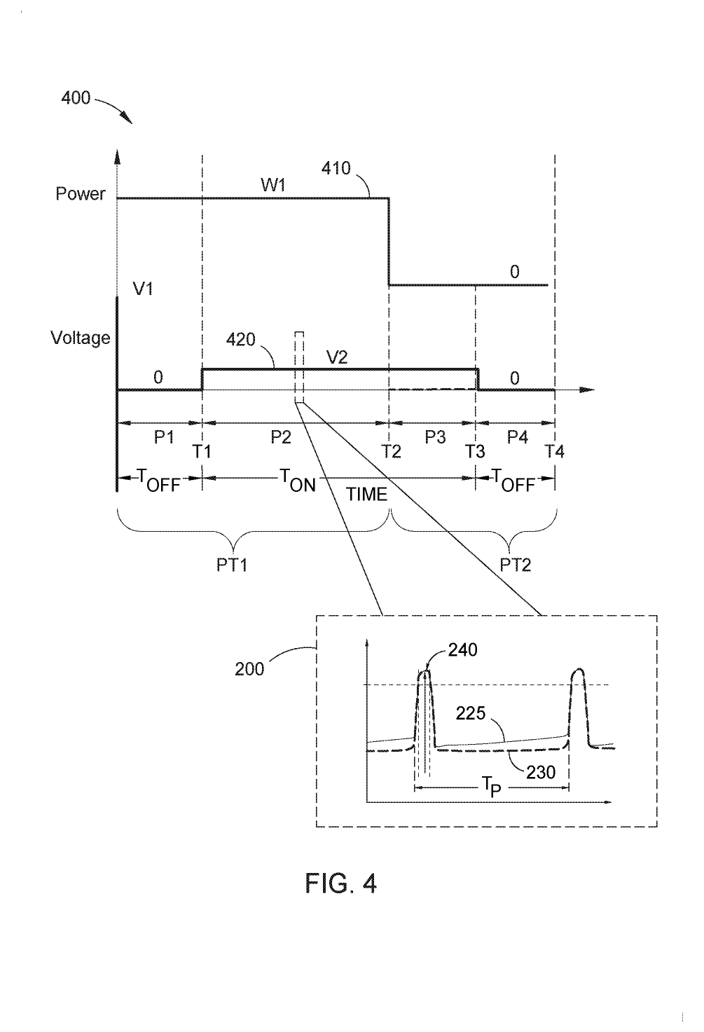

FIG. 3 is a flow diagram illustrating a method 300 of waveform generation, according to one or more of the embodiments described herein. FIG. 4 illustrates a graph 400 of example RF generator power 410 used to generate an RF waveform and example pulser voltage 420 used to generate a PV waveform during the method 300 of waveform generation, according to one or more of the embodiments described herein. Therefore, FIGS. 3 and 4 are herein described together for clarity. In some embodiments, modes of operation other than the method 300 may be used to enable the delivering of a PV waveform after halting the delivery of a RF waveform.

The method 300 includes, at activity 302, delivering a RF waveform at a frequency for a first period of time PT1 and then halting the delivery of the RF waveform for a second period of time PT2 using a RF generator (e.g., RF generator 171). The RF waveform may include a series of RF pulses. In some embodiments, the first period of time PT1 can include a first sub-period of time P1 and a second sub-period of time P2, and the second period of time PT2 can include a third sub-period of time P3 and a fourth sub-period of time P4. The first period of time PT1 and the second period of time PT2 can be cyclically repeated to form a series of RF pulses that each have a period (e.g., RF pulse period) that is equal to the sum of the first period of time PT1 and the second period of time PT2, or stated another way the sum of the first, second, third and fourth sub-periods of time. To deliver the RF waveform, the RF generator may provide the RF generator power 410 to an upper electrode (e.g., the chamber lid 123) and/or a lower electrode (e.g., RF baseplate 137) of a processing chamber (e.g., processing chamber 100). In some cases, the RF generator power 410 may be provided at power W1 to generate the RF waveform, and the power W1 may be 300 watts (w). The power W1 may be between 50 w and 8000 w. The RF waveform may be a sinusoidal waveform, and the frequency at which the RF waveform is delivered may be 13.56 MHz. In some embodiments, the second sub-period of time P2 begins at the end of the first sub-period of time P1 (e.g., at time T1), the third sub-period of time P3 begins at the end of the second sub-period of time P2 (e.g., at time T2), and the fourth sub-period of time P4 begins at the end of the third sub-period of time P3 (e.g., at time T3), as illustrated in FIG. 4In some cases, it is desirable to adjust one or more of the RF waveforms and/or PV waveform processing parameters during one or more of the plasma processing cycles of the repeated activities 302 and 304 that are performed multiple times. In one example, it may be desirable to adjust at least one of the RF pulse period, RF pulse duty cycle, the burst period T_{BD}, the voltage pulse burst duty cycle, the ignition voltage (e.g., second voltage V1), the first voltage V2, the voltage pulse period T_{P}, the RF power W1, and/or one or more of the sub-periods of time during one or more of the repeated cycles. As illustrated in FIGS. 3 and 4 and discussed in relation to method 300, the RF waveform provided by the RF generator may be asynchronously pulsed with the delivery of a PV waveform to ignite and/or sustain a plasma within a processing region of a plasma processing chamber.

It is believed that after the delivery of the RF waveform for the first period of time PT1, which includes the first sub-period of time P1 and second sub-period of time P2, the RF generator is turned off (e.g., the delivery of the RF waveform is halted). The removal of the RF power will cause a sudden drop in electron temperature and electron density in the plasma, and the number of electrons within the plasma will decay. It is believed that during the early stages of the RF “off” period, a large percentage of the fast electrons will be lost due to recombination or bombardment of the chamber walls, which will then leave a higher percentage of low energy electrons within the plasma until the plasma becomes extinguished after a period of time has elapsed. In some embodiments, it is desirable to assure that the second period of time PT2 is short enough to prevent the plasma from extinguishing during the one or more of the repeated cycles. The early stages of the RF “off” period of an RF pulse are often referred to as the afterglow period that can include a near-afterglow period, where the ion-ion plasma and weakly energetic electrons remain, and the plasma density is slowly decaying.

As noted above, during the near-afterglow period, which includes the third sub-period of time P3, a portion of a burst of voltage pulses of the PV waveform is provided by the pulser. The portion of the burst of voltage pulses causes the breakdown of the plasma during the near-afterglow period to occur at a lower rate than when the RF waveform provided to the plasma during the first period of time PT1. As a result, the PV waveform does not cause any densification in the plasma and generation of high energy electrons. Moreover, during the third period of time P3, collisions may occur between the fast ions (which had gained the momentum by crossing the high voltage sheath above the substrate 103 described above with respect to FIG. 2) and the slow neutrals in the plasma (e.g., plasma 101), which results in a charge exchange between the ions and the neutrals. As a result, the ions become slow ions, and the neutrals become fast neutrals. It is also believed that the processes performed herein will also have an effect on a narrower ion angular distribution function (IADF), and the charge exchange collision processes that generate directional neutrals. In addition, the PV waveform may be manipulated by changing the PV on-time, the duty cycle, the voltage pulse pulsing frequency, and the voltage set-point by modifying the pulser voltage 420 during the third period of time P3. It has been found that the techniques discussed herein enable the PV waveform to be used as an orthogonal knob for controlling the biasing of a plasma (e.g., plasma 101) during the third period of time P3 (e.g., the near-afterglow period). As a result, and as described above, a narrower IEDF and enhanced profile control during plasma-assisted etching processes may be achieved (e.g., when compared to plasma-assisted processes that utilize the RF generator to bias the plasma). The techniques discussed herein may be of particular help during clean-up plasma-assisted processes for high aspect ratio features.

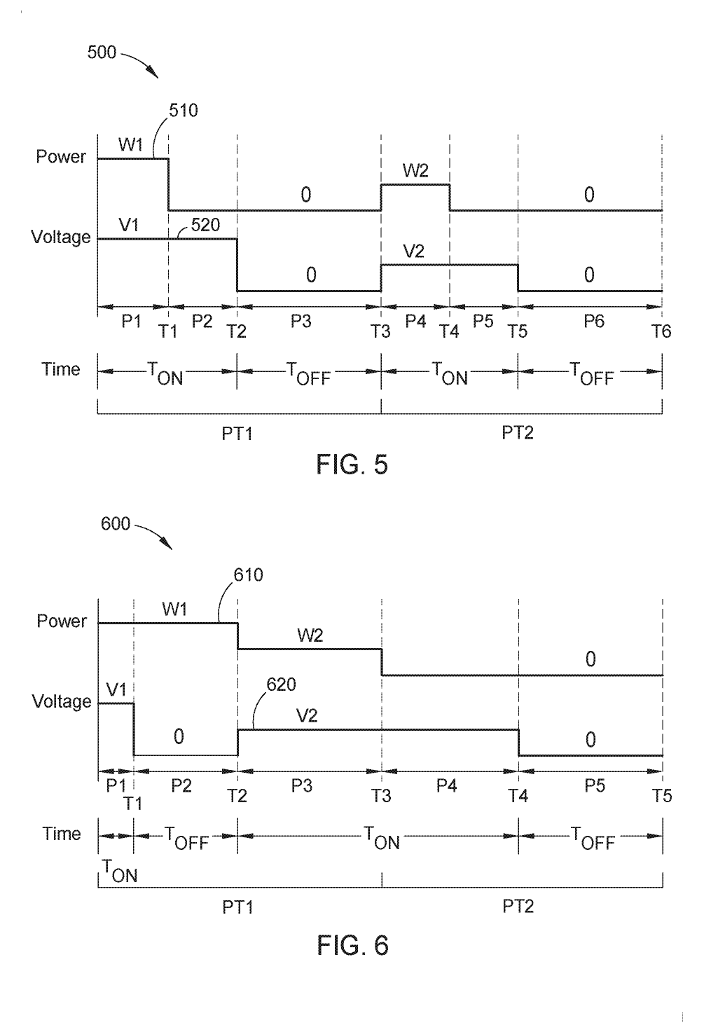

FIG. 5 illustrates graph 500 of example RF generator power 510 used to generate an RF waveform and example pulser voltage 520 used to generate a PV waveform, according to one or more of the embodiments described herein. The graph 500 may be substantially similar to the graph 400 but may represent a different pulsing scheme. In the pulsing scheme illustrated in the graph 500, the RF waveform is generated at a power W1 for a first sub-period of time P1, halted for a second sub-period of time P2 and a third sub-period of time P3 (e.g., the RF generator power 510 may be 0), generated at a power W2 for a fourth sub-period of time P4, and halted for a fifth sub-period of time P5 and a sixth sub-period of time P6 (e.g., the RF generator power 510 may be 0). The PV waveform is delivered at a first voltage V1 for the first sub-period of time P1 and the second sub-period of time P2, halted during the third sub-period of time P3 (e.g., the voltage delivered by the pulser may be 0), delivered at a second voltage V2 for the fourth sub-period of time P4 and the fifth sub-period of time P5, and halted during the sixth sub-period of time P6 (e.g., the voltage delivered by the pulser may be 0). In the pulsing scheme illustrated in the graph 500, each of the second sub-period of time P2 and the fifth sub-period of time P5 may be included in the near-afterglow period, and therefore the pulsing scheme may enable the benefits described above.

In the pulsing scheme illustrated in the graph 500, the power W1 may be higher than the power W2, and the first voltage V1 may be higher than the second voltage V2. In addition, the first sub-period of time P1, the second sub-period of time P2, and the third sub-period of time P3 may be 50% of the plasma processing cycle of the RF waveform (e.g., first period of time PT1), and the fourth sub-period of time P4, the fifth sub-period of time P5, and the sixth sub-period of time P6 may be 50% of the plasma processing cycle of the RF waveform (e.g., second period of time PT2).

FIG. 6 illustrates graph 600 of example RF generator power 610 used to generate an RF waveform and example pulser voltage 620 used to generate a PV waveform, according to one or more of the embodiments described herein. The graph 600 may be substantially similar to the graph 400 but may represent a different pulsing scheme. In the pulsing scheme illustrated in the graph 600, the RF waveform is generated at a power W1 for a first sub-period of time P1 and a second sub-period of time P2, generated at a power W2 for a third sub-period of time P3, and halted for a fourth sub-period of time P4 and fifth sub-period of time P5 (e.g., the RF generator power 510 may be 0). The PV waveform is delivered at a first voltage V1 for the first sub-period of time P1, halted during the second sub-period of time P2 (e.g., the voltage delivered by the pulser may be 0), delivered at a second voltage V2 for the third sub-period of time P3 and the fourth sub-period of time P4, and halted during the fifth sub-period of time P5 (e.g., the voltage delivered by the pulser may be 0). In the pulsing scheme illustrated in the graph 600, the fourth sub-period of time P4 may be included in the near-afterglow period, and therefore the pulsing scheme may enable the benefits described above.

In the pulsing scheme illustrated in the graph 600, the power W1 may be higher than the power W2, and the first voltage V1 may be higher than the second voltage V2. In addition, the first sub-period of time P1 and the second sub-period of time P2 may be 20% of the plasma processing cycle of the RF waveform, the third sub-period of time P3 may be 30% of the plasma processing cycle of the RF waveform, and the fourth sub-period of time P4 and the fifth sub-period of time P5 may be 50% of the plasma processing cycle of the RF waveform. The first sub-period of time P1, the second sub-period of time P2, and third sub-period of time P3 may form a first period of time PT1, and the fourth sub-period of time P4 and the fifth sub-period of time P5 may form a second period of time PT2.

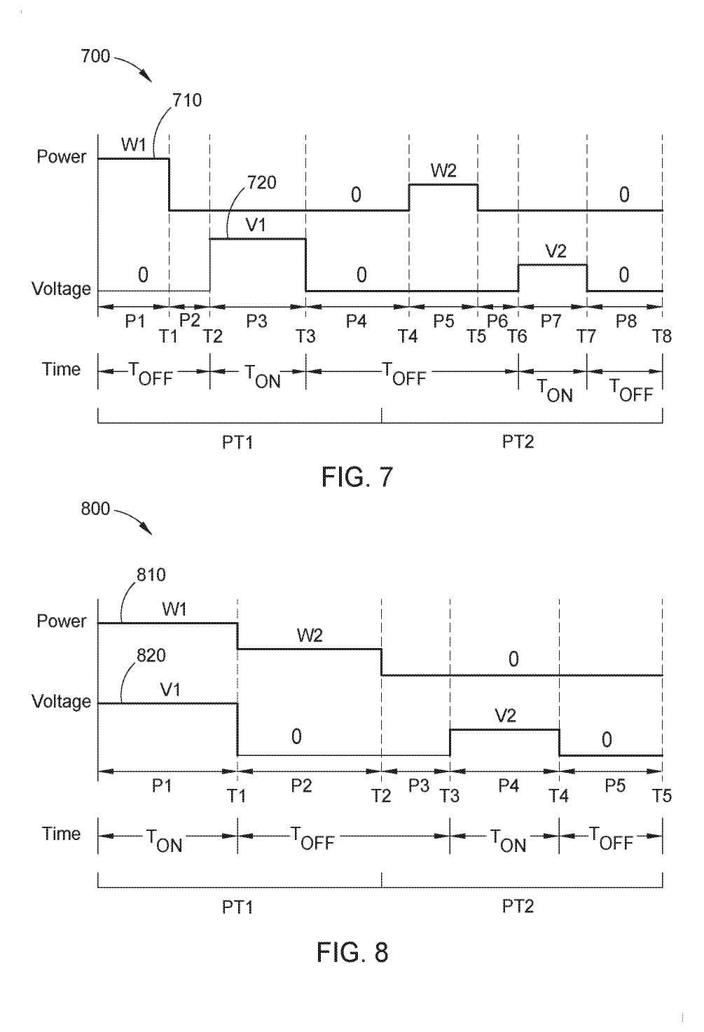

FIG. 7 illustrates graph 700 of example RF generator power 710 used to generate an RF waveform and example pulser voltage 720 used to generate a PV waveform, according to one or more of the embodiments described herein. The graph 700 may be substantially similar to the graph 400 but may represent a different pulsing scheme. In the pulsing scheme illustrated in the graph 700, the RF waveform is generated at a power W1 for a first sub-period of time P1, halted for a second sub-period of time P2, a third sub-period of time P3, and a fourth sub-period of time P4 (e.g., the RF generator power 510 may be 0), generated at a power W2 for a fifth sub-period of time P5, and halted for a sixth sub-period of time P6, a seventh sub-period of time P7, and an eighth sub-period of time P8 (e.g., the RF generator power 510 may be 0). The PV waveform is not delivered for the first sub-period of time P1 and the second sub-period of time P2, delivered at a first voltage V1 for the third sub-period of time P3, halted during the fourth sub-period of time P4, the fifth sub-period of time P5, and the sixth sub-period of time P6 (e.g., the voltage delivered by the pulser may be 0), delivered at a second voltage V2 for the seventh sub-period of time P7, and halted during the eighth sub-period of time P8 (e.g., the voltage delivered by the pulser may be 0). In the pulsing scheme illustrated in the graph 700, each of the third sub-period of time P3 and the seventh sub-period of time P7 may be included in the near-afterglow period, which occurs after a delay (e.g., the second sub-period of time P2 and the sixth sub-period of time P6, respectively). In this manner, the pulsing scheme illustrated in the graph 700 may enable the benefits described above.

In the pulsing scheme illustrated in the graph 700, the power W1 may be higher than the power W2, and the first voltage V1 may be higher than the second voltage V2. In addition, the first sub-period of time P1, the second sub-period of time P2, the third sub-period of time P3, and the fourth sub-period of time P4 may be 50% of the plasma processing cycle of the RF waveform (e.g., first period of time PT1), and the fifth sub-period of time P5, the sixth sub-period of time P6, the seventh sub-period of time P7, and the eighth sub-period of time P8 may be 50% of the plasma processing cycle of the RF waveform (e.g., second period of time PT2).

FIG. 8 illustrates graph 800 of example RF generator power 810 used to generate an RF waveform and example pulser voltage 820 used to generate a PV waveform, according to one or more of the embodiments described herein. The graph 800 may be substantially similar to the graph 400 but may represent a different pulsing scheme. In the pulsing scheme illustrated in the graph 800, the RF waveform is generated at a power W1 for a first sub-period of time P1, generated at a power W2 for a second sub-period of time P2, and halted during a third sub-period of time P3, a fourth sub-period of time P4, and a fifth sub-period of time P5 (e.g., the RF generator power 510 may be 0). The PV waveform is delivered at a first voltage V1 for the first sub-period of time P1, halted during the second sub-period of time P2 and the third sub-period of time P3 (e.g., the voltage delivered by the pulser may be 0), delivered at a second voltage V2 for the fourth sub-period of time P4, and halted during the fifth sub-period of time P5 (e.g., the voltage delivered by the pulser may be 0). In the pulsing scheme illustrated in the graph 800, the fourth sub-period of time P4 may be included in the near-afterglow period, which occurs after a delay (e.g., the third sub-period of time P3). In this manner, the pulsing scheme illustrated in the graph 800 may enable the benefits described above.

In the pulsing scheme illustrated in the graph 800, the power W1 may be higher than the power W2, and the first voltage V1 may be higher than the second voltage V2. In addition, the first sub-period of time P1 may be 20% of the plasma processing cycle of the RF waveform, the second sub-period of time P2 may be 30% of the plasma processing cycle of the RF waveform, and the third sub-period of time P3, the fourth sub-period of time P4, and the fifth sub-period of time P5 may be 50% of the plasma processing cycle of the RF waveform. The first sub-period of time P1 and the second sub-period of time P2 may form a first period of time PT1, and the third sub-period of time, the fourth sub-period of time P4, and the fifth sub-period of time P5 may form a second period of time PT2.

In some embodiments, the method 300 and the operations described herein may be performed by a system controller (e.g., the system controller 126 of FIG. 1). The system controller may include memory that includes computer-executable instructions and one or more processors configured to execute the computer-executable instructions and cause a waveform generator (e.g., a waveform generator that includes the RF generator 171 and the PV waveform generator 175) to perform the method 300 and any other operations described herein.

### Additional Considerations

In the above description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/-10% variation from the nominal value. It is to be understood that such a variation can be included in any value provided herein.

As used herein, “a processor,” “at least one processor” or “one or more processors” generally refers to a single processor configured to perform one or multiple operations or multiple processors configured to collectively perform one or more operations. In the case of multiple processors, performance of the one or more operations could be divided amongst different processors, though one processor may perform multiple operations, and multiple processors could collectively perform a single operation. Similarly, “a memory,” “at least one memory” or “one or more memories” generally refers to a single memory configured to store data and/or instructions, multiple memories configured to collectively store data and/or instructions.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

While the foregoing is directed to embodiments of the present disclosure, other and further embodiments of the disclosure may be devised without departing from the basic scope thereof, and the scope thereof is determined by the claims that follow.

We claim:

1. A method for waveform generation, comprising:
delivering a radio frequency (RF) waveform that comprises a plurality of RF pulses that comprise an RF signal provided at a first power level for a first period of time using an RF generator and then halting the delivery of the RF waveform for a second period of time; and
delivering a pulsed voltage waveform at a first pulse voltage for at least a portion of a third period of time using a pulser, wherein the delivery of the pulsed voltage waveform begins during the second period of time.

2. The method of claim 1, further comprising a fourth period of time that comprises a first sub-period of time and a second sub-period of time, wherein
the fourth period of time occurs during the second period of time,
the pulsed voltage waveform is delivered at the first pulse voltage during the first sub-period of time of the fourth period of time, and
the pulsed voltage waveform is delivered at a second pulse voltage during at least a portion of the second sub-period of time of the fourth period of time.

3. The method of claim 2, wherein the first pulse voltage is different from the second pulse voltage.

4. The method of claim 2, wherein the first pulse voltage is greater than the second pulse voltage.

5. The method of claim 1, further comprising halting delivery of the pulsed voltage waveform during a portion of the second period of time while the RF waveform is halted.

6. The method of claim 1, further comprising:
delivering the RF waveform at a second power level for a fourth period of time using the RF generator and then halting the delivery of the RF waveform for a fifth period of time; and
delivering the pulsed voltage waveform at a second pulse voltage for at least a portion of a sixth period of time using the pulser, wherein the delivery of the pulsed voltage waveform at the second pulse voltage overlaps with the halting of the delivery of the RF waveform during a portion of the fifth period of time.

7. The method of claim 6, wherein the first power level is greater than the second power level.

8. A method for waveform generation, comprising:
delivering a radio frequency (RF) waveform that comprises a plurality of RF pulses that comprise an RF signal provided at a first power level for a first period of time using an RF generator and then halting the delivery of the RF waveform for a second period of time;
delivering a pulsed voltage waveform at a first pulse voltage for at least a portion of a third period of time using a pulser, wherein the delivery of the pulsed voltage waveform overlaps with at least a portion of the delivery of the RF waveform during the first period of time; and
delivering a pulsed voltage waveform at a second pulse voltage for at least a portion of a fourth period of time using the pulser, wherein the delivery of the pulsed voltage waveform at the second pulse voltage overlaps with the halting of the delivery of the RF waveform during a portion of the second period of time.

9. The method of claim 8, wherein the first period of time includes a first sub-period of time and a second sub-period of time, wherein the RF waveform is delivered at the first power level during the first sub-period of time and at a second power level during the second sub-period of time.

10. The method of claim 9, wherein the first power level is greater than the second power level.

11. The method of claim 9, wherein the delivery of the pulsed voltage waveform at the first pulse voltage overlaps with the delivery of the RF waveform at the first power level during at least a portion of the first sub-period of time.

12. The method of claim 9, wherein the delivery of the pulsed voltage waveform at the second pulse voltage overlaps with the delivery of the RF waveform at the second power level during at least a portion of the second sub-period of time.

13. A waveform generator, comprising:
a system controller coupled to the waveform generator, the system controller comprising memory that includes computer-executable instructions and one or more processors configured to execute the computer-executable instructions and cause the waveform generator to:
deliver a radio frequency (RF) waveform that comprises a plurality of RF pulses that comprise an RF signal provided at a first power level for a first period of time using an RF generator and then halt the delivery of the RF waveform for a second period of time; and
deliver a pulsed voltage waveform at a first pulse voltage for at least a portion of a third period of time using a pulser, wherein the delivery of the pulsed voltage waveform begins during the second period of time.

14. The waveform generator of claim 13, wherein a synchronization signal is generated between the RF generator and the waveform generator to coordinate timing of the RF waveform and the pulsed voltage waveform.

15. The waveform generator of claim 13, wherein the second period of time includes a first sub-period of time and a second sub-period of time, wherein the pulsed voltage waveform is delivered at the first pulse voltage during the first sub-period of time of the second period of time and is delivered at a second pulse voltage during at least a portion of the second sub-period of time of the second period of time.

16. The waveform generator of claim 15, wherein the first pulse voltage is different from the second pulse voltage.

17. The waveform generator of claim 13, wherein the one or more processors are configured to execute the computer-executable instructions and cause the waveform generator to halt delivery of the pulsed voltage waveform during a portion of the second period of time while the RF waveform is halted.

18. The waveform generator of claim 13, wherein the one or more processors are configured to execute the computer-executable instructions and further cause the waveform generator to:
deliver the RF waveform at a second power level for a fourth
period of time using the RF generator and then halt the delivery of the RF waveform for a fifth period of time; and
deliver the pulsed voltage waveform at a second pulse voltage for at least a portion of a sixth period of time using the pulser, wherein the delivery of the pulsed voltage waveform at the second pulse voltage overlaps with the halting of the delivery of the RF waveform during a portion of the fifth period of time.

19. The waveform generator of claim 18, wherein a synchronization signal is generated between the RF generator and the waveform generator to coordinate timing of the RF waveform and the pulsed voltage waveform.

20. The waveform generator of claim 18, wherein the first power level is greater than the second power level.
